(19) United States
(12) Patent Application Publication
(10) Pub. No.: US 2026/0128207 A1
(43) Pub. Date: May 7, 2026

(54) INDUCTOR ARRAY

(71) Applicant: TAIYO YUDEN CO., LTD., Tokyo (JP)

(72) Inventors: Takayuki ARAI, Tokyo (JP); Naoya TERAUCHI, Tokyo (JP); Tomoo KASHIWA, Tokyo (JP)

(21) Appl. No.: 19/435,992

(22) Filed: Dec. 30, 2025

Related U.S. Application Data
(63) Continuation of application No. 17/388,178, filed on Jul. 29, 2021, now abandoned.

(30) Foreign Application Priority Data
Jul. 31, 2020 (JP) 2020-130041

(51) Int. Cl. H01F 27/28; H01F 27/255; H01F 27/29

(52) U.S. Cl. CPC H01F 27/2804; H01F 27/255; H01F 27/29; H01F 2027/2809

(57) ABSTRACT

An inductor array according to one embodiment includes: a base body containing metal magnetic particles and having a first surface; first, second, third, and fourth external electrodes provided on the base body in contact with the first surface; a first internal conductor provided in the base body and having one end connected to the first external electrode and the other end connected to the second external electrode; and a second internal conductor provided in the base body and having one end connected to the third external electrode and the other end connected to the fourth external electrode. The second internal conductor is spaced away from the first internal conductor in a reference direction. The ratio of the dimension in a direction perpendicular to a reference direction to the dimension in the reference direction of a section of the first internal conductor perpendicular to the current direction, is less than one.

### CROSS-REFERENCE TO RELATED APPLICATIONS

This application is a continuation of U.S. Patent Application No. 17/388,178 (filed on July 29, 2021), which claims the benefit of priority from Japanese Patent Application Serial No. 2020-130041 (filed on July 31, 2020), the contents of which are hereby incorporated by reference in their entirety.

### TECHNICAL FIELD

The present disclosure relates to an inductor array, a circuit board including the inductor array, and an electronic device including the circuit board.

### BACKGROUND

An inductor array including a plurality of inductors has been known. A plurality of inductors are packaged in a single chip to form such an inductor array. A typical conventional inductor array comprises a base body, a plurality of internal conductors provided in the base body and insulated from each other in the base body, and a plurality of external electrodes each of which is connected to either end of each of the plurality of internal conductors. Examples of the conventional inductor array are disclosed, for example, in Japanese Patent Application Publication No. 2016-006830 and Japanese Patent Application Publication No. 2019-153649.

In an inductor array, it may be desired to improve a coupling coefficient between the inductors. For example, when the inductor array is used as a common-mode choke coil, a transformer, or any other magnetically coupled inductor, it is desirable to have a high coupling coefficient between the inductors. Japanese Patent Application Publication No. 2016-131208 discloses a magnetically coupled inductor that increases the degree of coupling between the inductors by arranging the inductors such that the distances between the inductors are reduced.

Ferrite materials have been conventionally used to form a base body of an inductor array. Ferrite is suitable as a magnetic material for inductors because of its high magnetic permeability. However, the ferrite material has a drawback that magnetic saturation is likely to occur when a large current flows through the inductor. Therefore, when it is assumed that a large current flows through the inductor array, it is conceivable to use metal magnetic particles made of a soft magnetic metal material having a saturation magnetic flux density higher than that of ferrite as the material of the base body.

However, since the volume resistivity of the base body formed of metal magnetic particles is lower than that of a base body formed of ferrite material, a short circuit is more likely to occur between inner conductors when the metal magnetic particles are used as the material for the base body of the inductor array. Thus, if the distance between the internal conductors is reduced to increase the magnetic coupling between the inductors in the inductor array in which the base body formed of metal magnetic particles is used, short-circuit is more likely to occur between the internal conductors. Therefore, it is necessary to take a different approach to increase the coupling between inductors in the inductor array with the base body formed of metal magnetic particles than in the inductor array with the base body formed of a ferrite material.

### SUMMARY

One object of the invention is to overcome or mitigate at least a part of the above drawback. Specifically, one object of the invention is to provide a novel method of improving the magnetic coupling between inductors in an inductor array with a base body formed of metal magnetic particles.

Other objects of the invention will be made apparent through the entire description in the specification. The invention disclosed herein may address other drawbacks in addition to the drawback described above.

An inductor array according to one or more embodiments of the invention includes: a base body containing a plurality of metal magnetic particles and having a first surface; a first external electrode provided on the base body in contact with at least the first surface; a second external electrode provided on the base body in contact with at least the first surface; a third external electrode provided on the base body in contact with at least the first surface; a fourth external electrode provided on the base body in contact with at least the first surface; a first internal conductor provided in the base body; and a second internal conductor provided in the base body. According to one or more embodiments of the invention, the first internal conductor is configured in the base body such that it is connected at one end thereof to the first external electrode and connected at the other end thereof to the second external electrode. According to one or more embodiments of the invention, a first aspect ratio, which is the ratio of the dimension in a direction perpendicular to a reference direction to the dimension in the reference direction of a section of the first internal conductor perpendicular to the direction of current flowing therethrough, is less than one. According to one or more embodiments of the invention, the second internal conductor is configured in the base body such that it is connected at one end thereof to the third external electrode and connected at the other end thereof to the fourth external electrode. According to one or more embodiments of the invention, a second aspect ratio, which is the ratio of the dimension in a direction perpendicular to a reference direction to the dimension in the reference direction of a section of the second internal conductor perpendicular to the direction of current flowing therethrough, is less than one.

According to one or more embodiments of the invention, the first internal conductor extends linearly from the first external electrode to the second external electrode as viewed from a direction perpendicular to the first surface. According to one or more embodiments of the invention, the second internal conductor extends linearly from the third external electrode to the fourth external electrode as viewed from a direction perpendicular to the first surface.

According to one or more embodiments of the invention, the shape of the first internal conductor is identical to the shape of the second internal conductor as viewed from the reference direction.

According to one or more embodiments of the invention, the second internal conductor is disposed such that it overlaps the first internal conductor as viewed from the reference direction.

An inductor array according to one or more embodiments of the invention includes: a fifth external electrode provided on the base body in contact with at least the first surface; a sixth external electrode provided on the base body in contact with at least the first surface; and a third internal conductor provided in the base body. According to one or more embodiments of the invention, the third internal conductor is provided in the base body such that the third internal conductor is spaced away from the second internal conductor in the reference direction and disposed on a side opposite to the first internal conductor with respect to the second internal conductor, and the third internal conductor is connected to the fifth external electrode at one end and to the sixth external electrode at the other end. According to one or more embodiments of the invention, a third aspect ratio, which is the ratio of the dimension in a direction perpendicular to a reference direction to the dimension in the reference direction of a section of the second internal conductor perpendicular to the direction of current flowing therethrough, is less than one.

According to one or more embodiments of the invention, the shape of the third internal conductor is identical to the shape of the first or second internal conductor or both as viewed from the reference direction.

According to one or more embodiments of the invention, the third internal conductor is disposed at a position where the third internal conductor overlaps the first internal conductor and the second internal conductor as viewed from the reference direction.

According to one or more embodiments of the invention, the base body has a first end surface connected to the first surface, and the first internal conductor is arranged such that the fourth internal conductor faces the first end surface of the base body in the reference direction. According to one or more embodiments of the invention, a distance between the first internal conductor and the second internal conductor in the reference direction is smaller than a distance between the second internal conductor and the third internal conductor in the reference direction.

An inductor array according to one or more embodiments of the invention includes: a seventh external electrode provided on the base body in contact with at least the first surface; an eighth external electrode provided on the base body in contact with at least the first surface; and a fourth internal conductor provided in the base body. According to one or more embodiments of the invention, the fourth internal conductor is provided in the base body such that the fourth internal conductor is spaced away from the third internal conductor in the reference direction and disposed on a side opposite to the second internal conductor with respect to the third internal conductor, and the third internal conductor is connected to the seventh external electrode at one end and to the eighth external electrode at the other end. According to one or more embodiments of the invention, a fourth aspect ratio, which is the ratio of the dimension of a section of the fourth internal conductor in a direction perpendicular to a reference direction to the dimension in the reference direction of a section of the second internal conductor perpendicular to the direction of current flowing the fourth internal conductor, is less than one.

According to one or more embodiments of the invention, the shape of the fourth internal conductor is identical to the shape of at least the first, second, or third internal conductor as viewed from the reference direction.

According to one or more embodiments of the invention, the third internal conductor is disposed such that it overlaps the first and second internal conductors as viewed from the reference direction.

According to one or more embodiments of the invention, the base body has a second end surface that is connected to the first surface and opposes the first end surface, and the first internal conductor is arranged such that the fourth internal conductor faces the first end surface of the base body in the reference direction. According to one or more embodiments of the invention, a distance between the third internal conductor and the fourth internal conductor in the reference direction is smaller than a distance between the second internal conductor and the third internal conductor in the reference direction.

According to one or more embodiments of the invention, the base body has a first side surface and a second side surface opposing the first side surface, the first internal conductor is exposed at one end thereof to outside of the base body from the first side surface and is connected to the first external electrode at the one end, and the first internal conductor is also exposed at the other end thereof to outside of the base body from the second side surface and is connected to the second external electrode at the other end, and the second internal conductor is exposed at one end thereof to outside of the base body from the first side surface and is connected to the third external electrode at the one end, and the second internal conductor is also exposed at the other end thereof to outside of the base body from the second side surface and is connected to the fourth external electrode at the other end.

An embodiment of the invention relates to a circuit board comprising any one of the above inductors.

An embodiment of the present invention relates to an electronic device comprising the above circuit board.

According to the aspects disclosed herein, it is possible to improve the magnetic coupling between inductors in an inductor array with a base body formed of metal magnetic particles.

### BRIEF DESCRIPTION OF THE DRAWINGS

FIG. 1 is a perspective view of an inductor array according to one embodiment of the invention mounted on a mounting substrate.

FIG. 2 is an exploded view of the inductor array of FIG. 1.

FIG. 3 is a plan view of the inductor array of FIG. 1.

FIG. 4 is a schematic sectional view of the inductor array along the I-I line of FIG. 1.

FIG. 5 is a schematic enlarged sectional view schematically showing a section of internal conductors.

FIG. 6A schematically illustrates a line of a magnetic flux generated from the internal conductor included in the inductor array of FIG. 1.

FIG. 6B schematically illustrates a line of a magnetic flux generated from an internal conductor included in a conventional inductor array.

FIG. 7 is an exploded view of an inductor array according to another embodiment of the invention.

FIG. 8 is a perspective view of the inductor array according to another embodiment of the invention.

FIG. 9A is a perspective view of an internal conductor in the inductor array of FIG. 8 as viewed from the front.

FIG. 9B is a perspective view of another internal conductor in the inductor array of FIG. 8 as viewed from the front.

FIG. 10 is a plan view of the inductor array of FIG. 8.

FIG. 11 is a schematic sectional view of the inductor array of FIG. 6 along the line II-II.

FIG. 12 is a schematic perspective view of an inductor array according to yet another embodiment of the invention.

FIG. 13 is a schematic sectional view of the inductor array of FIG. 12 along the line III-III.

### DESCRIPTION OF THE EMBODIMENTS

Various embodiments of the present invention will be hereinafter described with reference to the accompanying drawings. Reference characters designating corresponding components are repeated as necessary throughout the drawings for the sake of consistency and clarity. For convenience of explanation, the drawings are not necessarily drawn to scale.

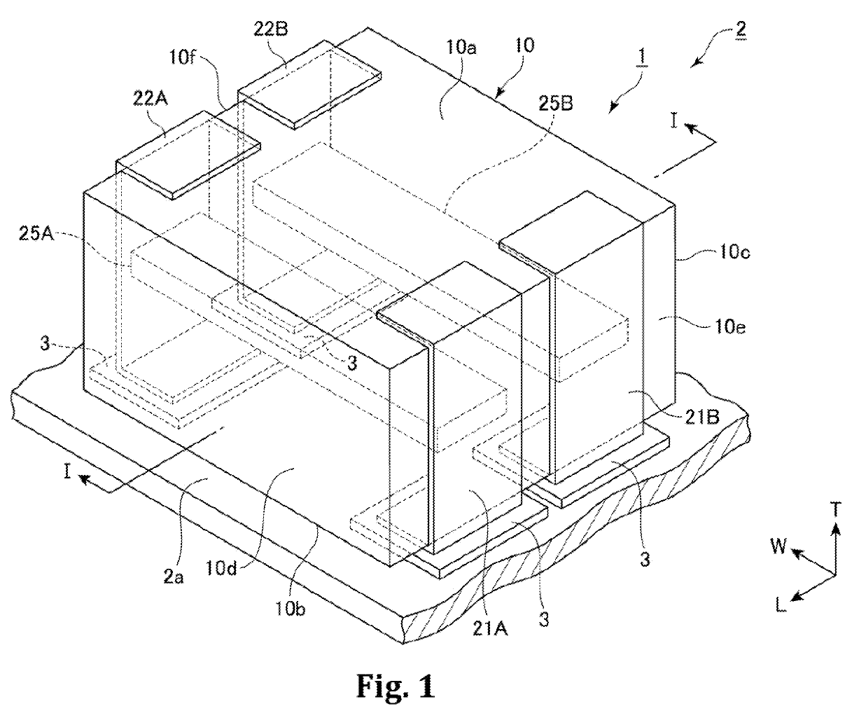

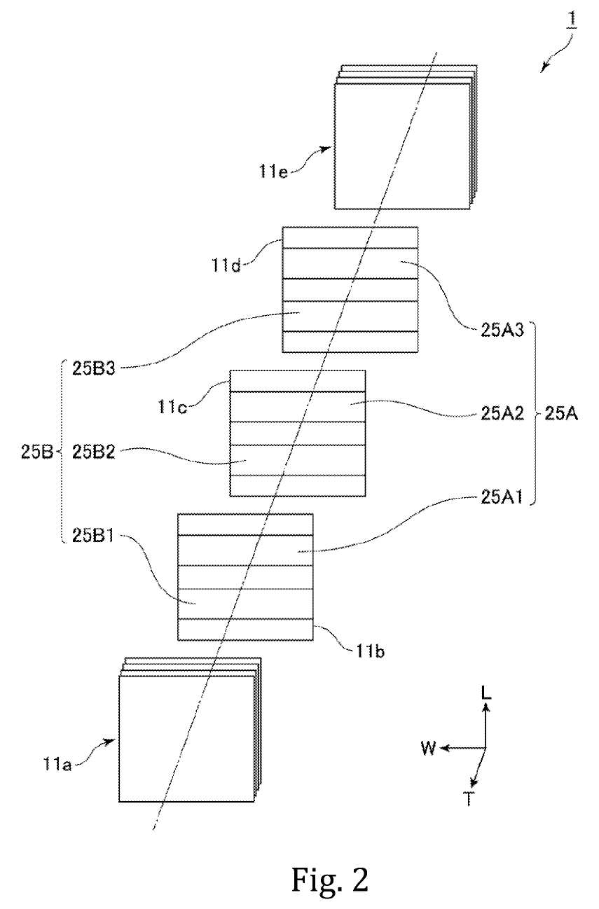

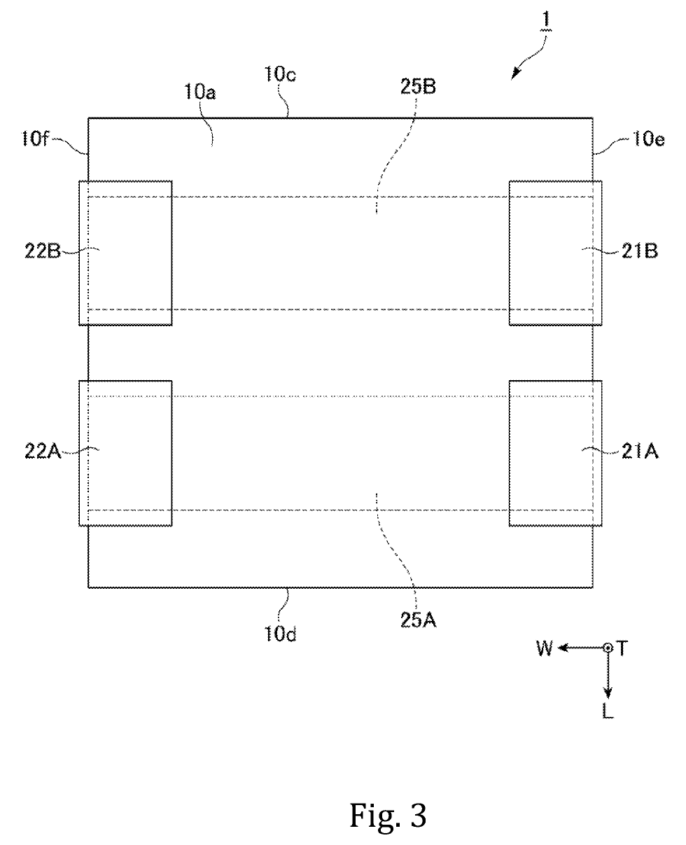

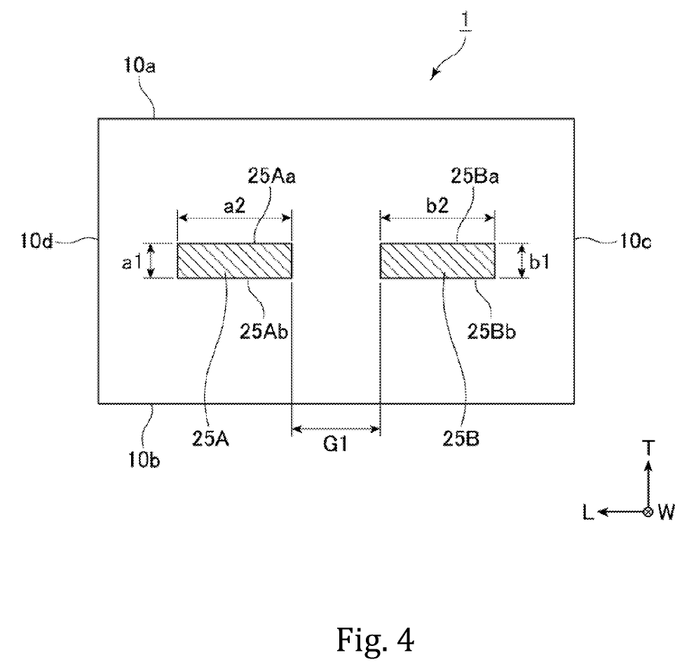

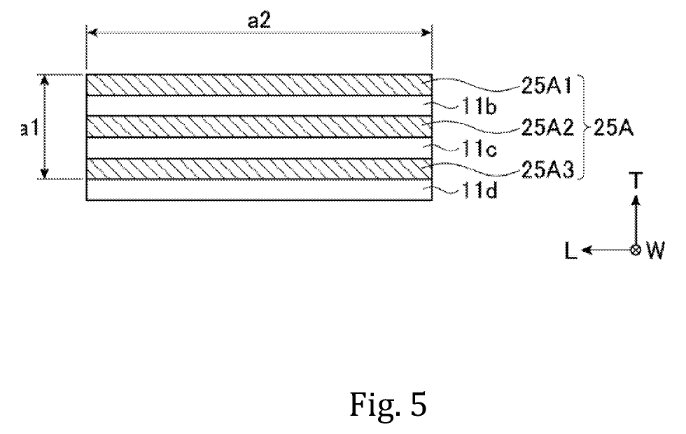

An inductor array 1 according to one or more embodiments of the present invention will now be described with reference to FIGS. 1 to 5. FIG. 1 is a perspective view of an inductor array 1 according to one embodiment of the invention, FIG. 2 is an exploded view of the inductor array 1, FIG. 3 is a plan view of the inductor array 1, FIG. 4 is a schematic sectional view of the inductor array 1 along the I-I line, and FIG. 5 is a schematic enlarged sectional view schematically showing a section of an internal conductor of the inductor array 1.

Each of the drawings shows the L axis, the W axis, and the T axis orthogonal to one another. In this specification, the "length" direction, the "width" direction, and the "thickness" direction of the inductor array 1 are referred to as the L-axis direction, W-axis direction, and T-axis direction in FIG. 1, respectively, unless otherwise construed from the context.

As illustrated, the inductor array 1 includes a base body 10, internal conductors 25A and 25B provided in the base body 10, and external electrodes 21A, 21B, 22A, 22B provided on a surface of the base body 10. The internal conductor 25A is coupled to the external electrode 21A at one end thereof and to the external electrode 22A at the other end thereof. The internal conductor 25B is coupled to the external electrode 21B at one end and to the external electrode 22B at the other end. The internal conductor 25A is disposed at a distance from the internal conductor 25B in the L-axis direction. Thus, the inductor array 1 includes a first inductor including the internal conductor 25A and the external electrodes 21A and 22A, and a second inductor including the internal conductor 25B and the external electrodes 21B and 22B.

The inductor array 1 is used in, for example, a large-current circuit through which a large electric current flows. More specifically, the inductor array 1 may be an inductor used in a DC-to-DC converter. Alternatively, the inductor array 1 may be a common mode choke coil used to remove common mode noise in a differential transmission circuit. The inductor array 1 may be a transformer. The inductor array 1 may be a magnetically-coupled inductor other than the above.

The inductor array 1 may be mounted on a mounting substrate 2a. The mounting substrate 2a has four land portions 3 provided thereon. The four external electrodes 21A, 21B, 22A, 22B of the inductor array 1 are arranged to face the corresponding lands 3 respectively when the inductor array 1 is mounted on the mounting substrate 2a. The inductor array 1 may be mounted on the mounting substrate 2 by soldering the external electrodes 21A, 21B, 22A, 22B and the corresponding lands 3, respectively. Thus, a circuit board 2 includes the inductor array 1 and the mounting substrate 2a on which the inductor array 1 is mounted. Various electronic components in addition to the inductor array 1 may be mounted on the mounting substrate 2a.

The circuit board 2 can be installed in various electronic devices. Electronic devices in which the circuit board 2 may be installed include smartphones, tablets, game consoles, servers, electrical components of automobiles, and various other electronic devices. The inductor array 1 may be a built-in component embedded in the mounting substrate 2a.

Since the inductor array 1 is formed as a single chip in which the first inductor with the internal conductor 25A and the external electrodes 21A, 22A and the second inductor with the internal conductor 25B and the external electrodes 21B, 22B are included, it is particularly suitable for small electronic devices that require high-density mounting of electronic components.

In the illustrated embodiment, the base body 10 may have a substantially rectangular parallelepiped shape. In one embodiment of the invention, the base body 10 has a length (the dimension in the L-axis direction) of 1.0 mm to 10 mm, a width (the dimension in the W-axis direction) of 0.2 mm to 10 mm, and a thickness (the dimension in the T-axis direction) of 0.2 mm to 10 mm. The base body 10 has a first region situated on a positive side in the L-axis direction with respect to a predetermined boundary on the L-axis, and a second region situated on a negative side with respect to the boundary in the L-axis direction. The first region includes the internal conductor 25A, and the second region includes the internal conductor 25B. In the similar manner, the base body 10 has a plurality of regions, each of which has a single inductor. The dimension of such a region of the base body 10 in the L-axis direction containing a single inductor is 0.5 mm to 5.0 mm. The dimensions of the base body 10 are not limited to those specified herein. The term "rectangular parallelepiped" or "rectangular parallelepiped shape" used herein is not intended to mean solely "rectangular parallelepiped" in a mathematically strict sense.

The base body 10 has a first principal surface 10a, a second principal surface 10b, a first end surface 10c, a second end surface 10d, a first side surface 10e, and a second side surface 10f. These six surfaces define the outer periphery of the base body 10. The first principal surface 10a and the second principal surface 10b are opposed to each other, the first end surface 10c and the second end surface 10d are opposed to each other, and the first side surface 10e and the second side surface 10f are opposed to each other. The first end surface 10c and the second end surface 10d connect the first principal surface 10a and the second principal surface 10b, and also connect the first side surface 10e and the second side surface 10f. Based on the position of the mounting substrate 2a, the first principal surface 10a lies on the top side of the base body 10, and therefore, the first principal surface 10a may be herein referred to as the "top surface," and the second principal surface 10a may be herein referred to as the "bottom surface."

The inductor array 1 is disposed such that the first principal surface 10a or the second principal surface 10b faces the mounting substrate 2a. The surface of the first principal surface 10a or the second principal surface 10b that faces the mounting substrate 2a is herein referred to as a "mounting surface". In the illustrated embodiment, the second principal surface 10b faces the mounting substrate 2a, so this second principal surface 10b is the "mounting surface". Thus, the second principal surface 10b may also be herein referred to as the "mounting surface 10b". Since the "mounting surface" of the base body 10 is the surface facing the mounting substrate 2a, any surface other than the second principal surface 10b may be the mounting surface. At least a part of all the external electrodes 21A, 22A, 21B, and 22B provided in the inductor array 1 contacts the mounting surface of the base body 10. In the embodiment shown in FIG. 1, a part of the external electrodes 21A, 22A, 21B, and 22B are each in contact with the first and second principal surfaces 10A and 10B so either the first principal surface 10A or the second principal surface 10B can be used as the mounting surface.

In the illustrated embodiment, the first and second principal surfaces 10a and 10b are parallel to the LW plane, the first and second end surfaces 10c and 10d are parallel to the WT plane, and the first and second side surfaces 10e and 10f are parallel to the TL plane.

The top-bottom direction of the inductor array 1 refers to the top-bottom direction in FIG. 1. The thickness direction of the inductor array 1 or the base body 10 may be the direction perpendicular to at least one of the top surface 10a and the mounting surface 10b. The length direction of the inductor array 1 or the base body 10 may be the direction perpendicular to at least one of the first end surface 10c and the second end surface 10d. The width direction of the inductor array 1 or the base body 10 may be the direction perpendicular to at least one of the first side surface 10e and the second side surface 10f. The width direction of the inductor array 1 or the base body 10 may be the direction perpendicular to the thickness direction and the length direction of the inductor array 1 or the base body 10.

In the illustrated embodiment, the external electrode 22A is attached to the base body 10 at a position spaced apart from the external electrode 21A in the W-axis direction, and the external electrode 21B is attached to the base body 10 at a position spaced apart from the external electrode 21A in the L-axis direction. The external electrode 22B is attached to the base body 10 at a position spaced apart from the external electrode 22A in the L-axis direction and spaced apart from the external electrode 21B in the W-axis direction. In the illustrated embodiment, the external electrodes 21A and 21B are provided in contact with the mounting surface 10b, the first side surface 10e, and the top surface 10a of the base body 10, and the external electrodes 22A and 22B are provided in contact with the mounting surface 10b, the second side surface 10f, and the top surface 10a of the base body 10. The external electrodes 21A and 21B may be provided on the base body 10 such that they are in contact with the mounting surface 10b and the first side surface 10e but not with the top surface 10a. The external electrodes 22A and 22B may be provided on the base body 10 such that they are in contact with the mounting surface 10b and the first side surface 10f but not with the top surface 10a. The shape and arrangement of the external electrodes 21A, 22B, 22A, and 22B are not limited to those explicitly described herein. The external electrodes 21A, 21B, 22A, 22B may have the same shape as each other or may be different from each other. Any pair selected from among the external electrodes 21A, 21B, 22A, and 22B may have the same shape as each other.

The base body 10 is made of a magnetic material. The magnetic material for the base body 10 may contain a plurality of metal magnetic particles. The metal magnetic particles contained in the magnetic material for the base body 10 are, for example, particles of (1) a metal such as Fe or Ni, (2) a crystalline alloy such as an Fe-Si-Cr alloy, an Fe-Si-Al alloy, or an Fe-Ni alloy, (3) an amorphous alloy such as an Fe-Si-Cr-B-C alloy or an Fe-Si-Cr-B alloy, or (4) a mixture thereof. The composition of the metal magnetic particles contained in the base body 10 is not limited to those described above. For example, the metal magnetic particles contained in the base body 10 may be particles of a Co-Nb-Zr alloy, an Fe-Zr-Cu-B alloy, an Fe-Si-B alloy, an Fe-Co-Zr-Cu-B alloy, an Ni-Si-B alloy, or an Fe-Al-Cr alloy. The Fe-based metal magnetic particles contained in the base body 10 may contain 80 wt% or more Fe. An insulating film may be formed on the surface of each of the metal magnetic particles. The insulating film may be an oxide film made of an oxide of the above metals or alloys. The insulating film provided on the surface of each of the metal magnetic particles may be, for example, a silicon oxide film provided by the sol-gel coating process.

In one or more embodiments, the average particle size of the metal magnetic particles in the base body 10 is from 1.0 µm to 20 µm. The average particle size of the metal magnetic particles contained in the base body 10 may be smaller than 1.0 µm or larger than 20 µm. The base body 10 may contain two or more types of metal magnetic particles having different average particle sizes.

In the base body 10, the metal magnetic particles may be bonded to each other with an oxide film formed by oxidation of an element included in the metal magnetic particles during a manufacturing process. The base body 10 may contain a binder in addition to the metal magnetic particles. When the base body 10 contains a binder, the metal magnetic particles are bonded to each other by the binder. The binder in the base body 10 may be formed, for example, by curing a thermosetting resin that has an excellent insulation property. Examples of a material for such a binder include an epoxy resin, a polyimide resin, a polystyrene (PS) resin, a high-density polyethylene (HDPE) resin, a polyoxymethylene (POM) resin, a polycarbonate (PC) resin, a polyvinylidene fluoride (PVDF) resin, a phenolic resin, a polytetrafluoroethylene (PTFE) resin, or a polybenzoxazole (PBO) resin.

In one or more embodiments of the invention, the relative magnetic permeability of the base body 10 is, for example, 100 or smaller. In one or more embodiments of the invention, the relative magnetic permeability of the base body 10 is, for example, 30 or greater. When the inductor array 1 is used in a high frequency circuit, the specific permeability of the base body 10 may be reduced. For example, when the inductor array 1 operates at a frequency of about 100 MHz, the lower limit of the specific permeability of the base body 10 may be 20 or greater. When the array inductor 1 operates at a higher frequency band, the lower limit of the specific permeability of the base body 10 may be 10 or greater. In one or more embodiments of the invention, the relative magnetic permeability of the base body 10 is, for example, in the range of 30 to 100 (both inclusive). The base body 10 may be configured to have the specific permeability of in the range of 30 to 100 in all regions of the base body. As described above, the inductor array 1 may be used in DC to DC converters where a low inductance is required. When the base body 10 has a specific permeability of 100 or smaller, it is easy to achieve a required low inductance. When the base body 10 has a specific permeability of 100 or smaller, it is also easy to achieve high current characteristics. When the base body 10 has a specific permeability of 100 or smaller, it is also easy to achieve high insulation properties. When the base body 10 has a specific permeability of 100 or smaller, it is possible to reduce the chance of magnetic saturation. Therefore, there is no need to provide a magnetic gap in the base body 10 to improve the DC superposition characteristics. In one or more embodiments of the invention, the base body 10 does not have a hollow magnetic gap (air gap). In one or more embodiments of the invention, as for the space between the internal conductor 25A and the internal conductor 25B in the base body 10, the there is no air gap extending between the internal conductor 25A and the internal conductor 25B.

As mentioned above, the specific permeability of the base body 10 of the inductor array 1 takes a small value, such as 100 or smaller, so that the inductance L of each line of inductor included in the inductor array 1 also takes a small value. Since the inductance of each line of inductor is low, magnetic saturation is unlikely to occur in the inductor array 1. As a result, it is possible to let a large current flow through each line of inductor included in the inductor array 1. Therefore, in one or more embodiments of the invention, for each line of inductor included in the inductor array 1, an energy density Ed expressed as the product of its inductance L and the square of the current I flowing therethrough divided by the volume V of the inductor (that is, Ed = L x I²/V) can be made larger. For example, when the inductance L of each line of inductor in the inductor array 1 is smaller than 100 nH, Ed is 1500 nH-A²/mm³. When the inductance L of each line of inductor in the inductor array 1 is smaller than 50 nH, Ed is 2000 nH-A²/mm³. When the inductance L of each line of inductor in the inductor array 1 is smaller than 25 nH, Ed is 2500 nH-A²/mm³.

The internal conductor 25A and the internal conductor 25B are provided inside the base body 10. In the illustrated embodiment, the internal conductor 25A is exposed at one end thereof to the outside of the base body 10 from the first side surface 10e and is connected to the external electrode 21A at the one end. The internal conductor 25A is also exposed at the other end thereof to the outside of the base body 10 from the second side surface 10f and is connected to the external electrode 22A at the other end. In this manner, the internal conductor 25A is connected at one end thereof to the external electrode 21A and connected at the other end thereof to the external electrode 22A. Similarly, the internal conductor 25B is exposed at one end thereof to the outside of the base body 10 from the first side surface 10e and is connected to the external electrode 21B at the one end. The internal conductor 25B is also exposed at the other end thereof to the outside of the base body 10 from the second side surface 10f and is connected to the external electrode 22B at the other end. In this manner, the internal conductor 25B is connected at one end thereof to the external electrode 21B and connected at the other end thereof to the external electrode 22B. In this way, to connect the internal conductors 25A and 25B to the external electrodes, the internal conductors 25A and 25B are not directly connected to a first surface, but are connected to the first surface outside the substrate 10 via the outer electrodes 21A, 22A, 21B and 22B formed on the first and second side surfaces. Therefore, the volume of the base body 10 can be increased relative to the overall volume of the inductor array 1. Consequently, it is possible to increase the ratio of the volume of the base body 10 made of a magnetic material in the inductor array 1, and thus to increase the saturation magnetic flux density of the base body 10.

As shown in FIG. 3, the internal conductor 25A extends linearly from the external electrode 21A to the second external electrode 22A in plan view (as viewed from the T axis). Stated differently, the internal conductor 25A has no parts facing each other in the base body 10 in a plan view. Herein, when the internal conductor 25A has no parts facing each other in the base body in a plan view, it can be said that the internal conductor 25A extends linearly from the external electrode 21A to the external electrode 22A. Thus, compared with conventional inductors that have internal conductors with parts facing each other in plan view, the insulation reliability (withstand voltage) can be increased without changing the volume resistivity of the base body 10. The internal conductor 25A may be disposed on a straight line drawn from the external electrode 21 to the external electrode 22. In the illustrated embodiment, the internal conductor 25A has a rectangular parallelepiped shape.

The internal conductor 25A may be formed of a single conductor layer or multiple conductor layers arranged in parallel between the external electrode 21A and the external electrode 22A. In the illustrated embodiment, the internal conductor 25A has three conductor patterns 25A1 to 25A3, which are arranged in parallel between the external electrode 21A and the external electrode 22A. The number of conductor patterns included in the internal conductor 25A is not limited to three, but may be two, or four or more. As shown in FIG. 2, the conductor patterns 25A1 to 25A3 all extend linearly from the external electrode 21 to the external electrode 22, and are identical or similar in shape to each other. Since each of the conductor patterns 25A1 to 25A3 has the same or similar shape to each other, there is no potential difference between the portions of the conductor patterns 25A1 to 25A3 that face each other in the base body 10. Therefore, even when the internal conductor 25A is formed of a plurality of conductor layers, it is possible to make the insulation reliability (withstand voltage) required of the base body 10 same as that of the internal conductor 25A formed of a single conductor layer. Adjacent conductor layers among the plurality of conductor layers included in the internal conductor 25A may be connected to each other in the base body 10, for example, by vias. The internal conductor 25A and the internal conductor 25B may be formed of a plurality of conductors that are connected to each other by means other than through holes. The internal conductor 25A and the internal conductor 25B may each include a plurality of conductors that are not connected to each other in the base body 10, but are connected by the external electrodes 21A and 22A and the external electrodes 21B and 22B.

In the illustrated embodiment, each of the conductor patterns 25A1 to 25A3 has a rectangular parallelepiped or plate-like shape. Therefore when a voltage is applied between the external electrode 21A and the external electrode 22A, the current flows in the direction of the W axis in each of the conductor patterns 25A1 to 25A3.

In one or more embodiments of the invention, the internal conductor 25B may have the same shape as the internal conductor 25A. For example, the internal conductor 25B may extend linearly from the external electrode 21B to the second external electrode 22B in plan view (as viewed from the T axis). As shown in FIG. 2, the internal conductor 25B in the illustrated embodiment includes three conductor patterns 25B1 to 25B3 disposed in parallel between the external electrode 21B and the external electrode 22B. In the illustrated embodiment, each of the conductor patterns 25B1 to 25B3 has a rectangular parallelepiped or plate-like shape. Therefore when a voltage is applied between the external electrode 21B and the external electrode 22B, the current flows in the direction of the W axis in each of the conductor patterns 25B1 to 25B3. The shape of the internal conductor 25B viewed from the L-axis direction may be the same as a shape of the internal conductor 25A viewed from the L-axis direction.

In one or more embodiments of the invention, the shape of the internal conductor 25A may be the same as the shape of the internal conductor 25B. By making the shape of the internal conductor 25A identical to the shape of the internal conductor 25B, it becomes easy to uniform the electrical characteristics of each line of inductor included in the inductor array 1.

As shown in FIG. 2, the inductor array 1 may have a multilayer structure of multiple magnetic layers. In FIG. 2, the external electrodes 21A, 22A, 21B, and 22B are not shown for convenience of description. In the illustrated embodiment, the base body 10 includes magnetic layers 11a to 11e. Each of the magnetic layers 11a to 11e is made of a magnetic material. The base body 10 includes the magnetic layer 11a, the magnetic layer 11b, the magnetic layer 11c, the magnetic layer 11d, and the magnetic layer 11e, which are stacked together in the stated order from the negative side to the positive side in the T-axis direction. The magnetic layer 11a and the magnetic layer 11e are disposed so as to cover the internal conductors 25A and 25B on both sides in the T-axis direction, and thus these magnetic layers may be referred to as the cover layers. In the illustrated embodiment, each of the magnetic layers 11a and 11e includes a plurality of magnetic films. The magnetic layer 11b, the magnetic layer 11c, and the magnetic layer 11d may also include a plurality of magnetic films.

In the illustrated embodiment, the conductor patterns 25A1 and 25B1 are provided on a surface of the magnetic layer 11b on one side, the conductor patterns 25A2 and 25B2 are provided on a surface of the magnetic layer 11c on one side, and the conductor patterns 25A3 and 25B3 are provided on a surface of the magnetic layer 11d on one side. Specifically, the conductor patterns 25A1 and 25B1 are provided on the surface on the positive side in the T-axis direction among the pair of surfaces of the magnetic layer 11b intersecting the T axis. Similarly the conductor patterns 25A2 and 25B2 are provided on the surface on the positive side in the T-axis direction among the pair of surfaces of the magnetic layer 11c intersecting the T axis, and the conductor patterns 25A3 and 25B3 are provided on the surface on the positive side in the T-axis direction among the pair of surfaces of the magnetic layer 11d intersecting the T axis. The conductor patterns 25A1, 25A2, 25A3, 25B1, 25B2, and 25B3 are formed by, for example, printing a conductive paste made of a highly conductive metal or alloy on each magnetic layer by screen printing. A conductive material contained in the conductive paste may be Ag, Pd, Cu, Al, or alloys thereof. The conductor patterns 25A1, 25A2, 25A3, 25B1, 25B2, and 25B3 may be formed using other methods and materials. For example, the conductor patterns 25A1, 25A2, 25A3, 25B1, 25B2, and 25B3 may be formed by sputtering, ink-jetting, or any other known methods.

With further reference to FIGS. 4 and 5, the arrangement and sectional shape of the internal conductors 25A and 25B will be described. FIG. 4 is the schematic sectional view showing a cross-section of the inductor array 1 along the I-I line, and FIG. 5 is an enlarged view showing the vicinity of the internal conductor 25A in the cross-section shown in FIG. 4. FIG. 4 shows a section of the internal conductor 25A cut along a plane perpendicular to the W-axis direction. As described above, the current flows through each of the internal conductors 25A and 25B (or through each of the conductor patterns 25A1 to 25A3 that form the internal conductor 25A and through each of the conductor patterns 25B1 to 25B3 that form the internal conductor 25B) in the W-axis direction. Therefore FIGS. 4 and 5 show the sections of the internal conductors 25A and 25B cut along the plane perpendicular to the direction of the current flowing through the internal conductors 25A and 25B. The term "parallel," "orthogonal," and "perpendicular" used herein is not intended to mean solely "parallel," "orthogonal," and "perpendicular" in a mathematically strict sense.

In one or more embodiments of the invention, the internal conductor 25B is disposed at a distance G1 from the internal conductor 25A in the L-axis direction. In other words, the spacing between the internal conductor 25A and the internal conductor 25B in the L-axis direction is G1. The spacing G1 between the internal conductor 25A and the internal conductor 25B is the distance in the L-axis direction between an end of the internal conductor 25A situated on the negative side of the L-axis direction and an end of the internal conductor 25B situated on the positive side of the L-axis direction. In one or more embodiments of the invention, the spacing G1 between the internal conductor 25A and the internal conductor 25B is the clearance necessary to ensure insulation between the internal conductor 25A and the internal conductor 25B, for example, 0.1 mm or more or 0.25 mm or more. When magnitudes of currents flowing through the internal conductor 25A and the internal conductor 25B and magnitudes of voltages applied to the internal conductor 25A and the internal conductor 25B are the same or close to each other, there will be no large potential difference between the internal conductor 25A and the internal conductor 25B and therefore the distance between the internal conductor 25A and the internal conductor 25B can be made smaller. When the magnitudes of currents flowing through the internal conductor 25A and the internal conductor 25B and the magnitudes of voltages applied to the internal conductor 25A and the internal conductor 25B are the same or close to each other, the spacing G1 between the internal conductor 25A and the internal conductor 25B may be 0.1 mm or more, such as about 0.12 mm.

In one or more embodiments of the invention, the internal conductor 25B is disposed such that it overlaps the internal conductor 25A as viewed from the L-axis direction. As shown in FIG. 4, the position of an upper surface 25Aa of the internal conductor 25A in the T-axis direction may coincide with the position of an upper surface 25Ba of the internal conductor 25B in the T-axis direction. The position of a lower surface 25Ab of the internal conductor 25A in the T-axis direction may coincide with the position of the lower surface 25Bb of the internal conductor 25B in the T-axis direction. When these internal conductors are arranged in this way, it is possible to further improve the coupling coefficient between the internal conductor 25A and the internal conductor 25B, and also reduce the thickness of the inductor array 1.

As shown in FIGS. 4 and 5, the section of the internal conductor 25A cut along the plane perpendicular to the direction of the current flowing through the internal conductor 25A has a dimension a2 in a reference direction and a dimension a1 in a direction perpendicular to the reference direction (the T-axis direction in the illustrated example). In the illustrated embodiment, the reference direction coincides with the L-axis direction, and the direction perpendicular to the reference direction of the section of the internal conductor 25A cut along the plane perpendicular to the current flowing direction coincides with the T-axis direction. As shown in FIG. 5, when the internal conductor 25A includes the conductor patterns 25A1 to 25A3 stacked in the T-axis direction, the dimension a1 of the section of the internal conductor 25A in the T-axis direction perpendicular to the L-axis direction refers to the distance between a lower surface of the bottom conductor pattern 25A3 and an upper surface of the top conductor pattern 25A1. Thus, when the internal conductor 25A includes two more conductor layers (conductor patterns) stacked on top of each other, the dimension of the internal conductor 25A in the stacking direction is the distance between an outer surface of a conductor layer situated at one end in the stacking direction and an outer surface of a conductor layer situated at the other end in the stacking direction. The ratio of a1 to a2 (a1/a2) is defined as a first aspect ratio. In one or more embodiments of the invention, the first aspect ratio is less than one (1). Since the internal conductor 25A is disposed away from the internal conductor 25B in the L-axis direction, the internal conductor 25A is separated from the internal conductor 25B in the reference direction.

Similarly, the section of the internal conductor 25B cut along a plane perpendicular to the direction of the current flowing through the internal conductor 25B has a dimension b2 in a reference direction and a dimension b1 in a direction perpendicular to the reference direction. In the illustrated embodiment, the reference direction coincides with the L-axis direction, and the direction perpendicular to the reference direction of the section of the internal conductor 25B cut along the plane perpendicular to the current flowing direction coincides with the T-axis direction. The ratio of b1 to b2 (b1/b2) is defined as a second aspect ratio. When the internal conductor 25B includes the conductor patterns 25B1 to 25B3 stacked in the T-axis direction, the dimension b1 of the section of the internal conductor 25B in the T-axis direction perpendicular to the L-axis direction refers to the distance between a lower surface of the bottom conductor pattern 25B3 and an upper surface of the top conductor pattern 25B1. Thus, when the internal conductor 25B includes two more conductor layers (conductor patterns) stacked on top of each other, the dimension of the internal conductor 25B in the stacking direction is the distance between an outer surface of a conductor layer situated at one end in the stacking direction and an outer surface of a conductor layer situated at the other end in the stacking direction. In one or more embodiments of the invention, the second aspect ratio of the internal conductor 25B is less than one (1).

As mentioned above, the internal conductor 25A may include multiple conductor layers arranged in parallel between the external electrode 21A and the external electrode 22A. In this case, the distance between an outer end of a conductor layer situated at one end (left end in FIG. 3) in the reference direction (L-axis direction) among the plurality of conductor layers forming the internal conductor 25A and an outer end of a conductor layer situated at the other end (right end in FIG. 3) in the reference direction (L-axis direction) among the plurality of conductor layers forming the internal conductor 25A may be defined as the dimension a2, which is the dimension of the section of the internal conductor 25A in the reference direction (L-axis direction). Similarly, when the internal conductor 25B includes multiple conductor layers arranged in parallel between the external electrode 21B and the external electrode 22B, the distance between an outer end of a conductor layer situated at one end (left end in FIG. 3) in the reference direction (L-axis direction) among the plurality of conductor layers forming the internal conductor 25B and an outer end of a conductor layer situated at the other end (right end in FIG. 3) in the reference direction (L-axis direction) among the plurality of conductor layers forming the internal conductor 25B may be defined as the dimension b2, which is the dimension of the section of the internal conductor 25B in the reference direction (L-axis direction).

FIG. 4 shows the sections of the internal conductors 25A and 25B cut along a plane that is parallel to the LT plane and passes the center of the base body 10. The sections of the internal conductors 25A and 25B shown in FIG. 4 are orthogonal to the direction of the current flowing through the internal conductors 25A and 25B, respectively, as described above. In one or more embodiments of the invention, not only for the sections of the internal conductors 25A and 25B cut along the plane that is parallel to the LT plane and passes the center of the base body 10 as illustrated in FIG. 4, but also for any section of the internal conductor 25A orthogonal to the direction of the current flowing through the internal conductor 25A, the first aspect ratio is less than one, and for any section of the internal conductor 25B orthogonal to the direction of the current flowing through the internal conductor 25B, the second aspect ratio is less than one. In one or more embodiments of the invention, for entire length of the internal conductors 25A and 25B along the direction of the current flowing (W-axis direction in the embodiment shown) through the internal conductors 25A and 25B, the first and second aspect ratios are less than one.

The section of the internal conductor 25A cut along the plane perpendicular to the direction of the current flowing through the internal conductor 25A may be herein simply referred to as a "section of the internal conductor 25A" without specifying the cut plane for brevity of description. Similarly, the section of the internal conductor 25B cut along the plane perpendicular to the direction of the current flowing through the internal conductor 25B may be herein simply referred to as a "section of the internal conductor 25B" without specifying the cut plane for brevity of description.

In the illustrated embodiment, since the first aspect ratio is smaller than one, the dimension a1 of the section of the internal conductor 25A in the direction perpendicular to the L-axis direction is smaller than the dimension a2 in the L-axis direction. Similarly, since the second aspect ratio is smaller than one, the dimension b1 of the cross section of the internal conductor 25B in the direction perpendicular to the L-axis direction is larger than the dimension b2 in the L-axis direction. In the illustrated embodiment, the first aspect ratio and the second aspect ratio are approximately 0.25. Each of the first and second aspect ratios may be smaller than 0.9, 0.8, 0.7, 0.6, 0.5, 0.4, 0.3, 0.2, 0.1, or 0.05. The first aspect ratio and the second aspect ratio may be the same or may be different.

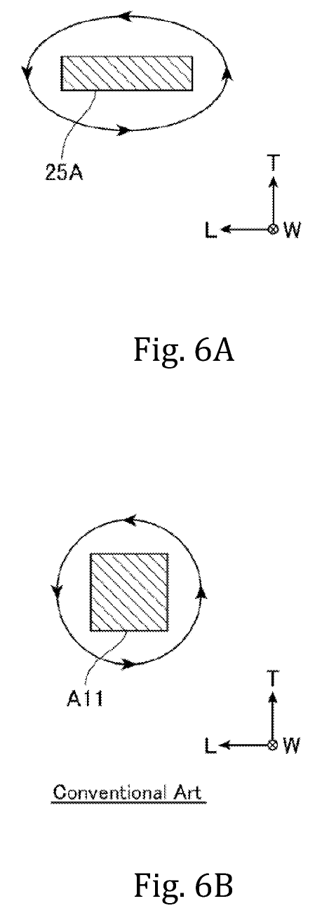

Next, with further reference to FIGS. 6A and 6B, the magnetic flux generated around the internal conductor 25A due to change in the current flowing through the internal conductor 25A will be now described. FIG. 6A schematically illustrates a line of a magnetic flux generated around the internal conductor 25A due to change in the electric current flowing through the internal conductor 25A, and FIG. 6B schematically illustrates a line of a magnetic flux generated around a conventional internal conductor due to change in electric current flowing through the internal conductor. FIG. 6B shows a section of an internal conductor A11 cut along the plane perpendicular to the direction of current flowing through the internal conductor A11. The section of this internal conductor A11 has a square shape with the same area as the section of the internal conductor 25A shown in FIG. 6A. The sections of conventional internal conductors typically have a square or circular shape in order to reduce the Rdc of the internal conductor.

As shown in FIG. 6A, the magnetic flux generated around the internal conductor 25A when the current flowing through the internal conductor 25A changes tends to face the L-axis direction because the first aspect ratio of the internal conductor 25A is smaller than one. Whereas the direction of the magnetic flux generated around the conventional internal conductor A11, which has a square cross section, does not tend to distribute in any particular direction as shown in FIG. 6B. Therefore, by making the first aspect ratio of the internal conductor 25A smaller than one, the magnetic flux generated around the internal conductor 25A due to change in the current flowing through the internal conductor 25A can easily reach other internal conductor(s) (e.g., the internal conductor 25B) that is situated adjacent to the internal conductor 25A in the L-axis direction. Consequently, by making the first aspect ratio of the internal conductor 25A smaller than one, the magnetic coupling between the internal conductor 25A and other internal conductor (e.g., the internal conductor 25B) adjacent to the internal conductor 25A in the L-axis direction can be improved. When the inductor array 1 is mounted on the mounting substrate 2a, the mounting space can be saved compared to the case where two inductor elements are mounted on the mounting substrate 2a, and the coupling between the internal conductors can be made stronger. In the inductor array 1 according to one or more embodiment of the invention, by making the first aspect ratio of the internal conductor 25A and the second aspect ratio of the internal conductor 25B smaller than one, it is possible to improve the magnetic coupling between the internal conductor 25A and the internal conductor 25B. When the inductor array 1 includes three or more sets of inductors, non-adjacent inductors can be also indirectly coupled to each other through adjacent inductors. Thus, by improving the coupling between the sets of inductors included in the inductor array 1, a ripple current flowing through the inductors can be reduced compared to an inductor array with a small coupling between inductors (e.g., an inductor array where the aspect ratio of multiple inductors is greater than one). In this way, the coupling between the lines of inductors included in the inductor array 1 (the coupling between the inductor that includes the internal conductor 25A and the inductor that includes the internal conductor 25B) can be enhanced. Thus when a wiring pitch in the circuit in which the inductor array 1 is mounted is small (for example, 0.2 mm or less), the ripple current flowing through the internal conductors 25A and 25B can be reduced. For example, in a circuit where the inductor array 1 is connected to multiple semiconductor devices (e.g., power transistors), it is possible to supply power to each of the multiple semiconductor devices independently by the internal conductor 25A and the internal conductor 25B while suppressing the ripple current flowing through the internal conductor 25A and the internal conductor 25B.

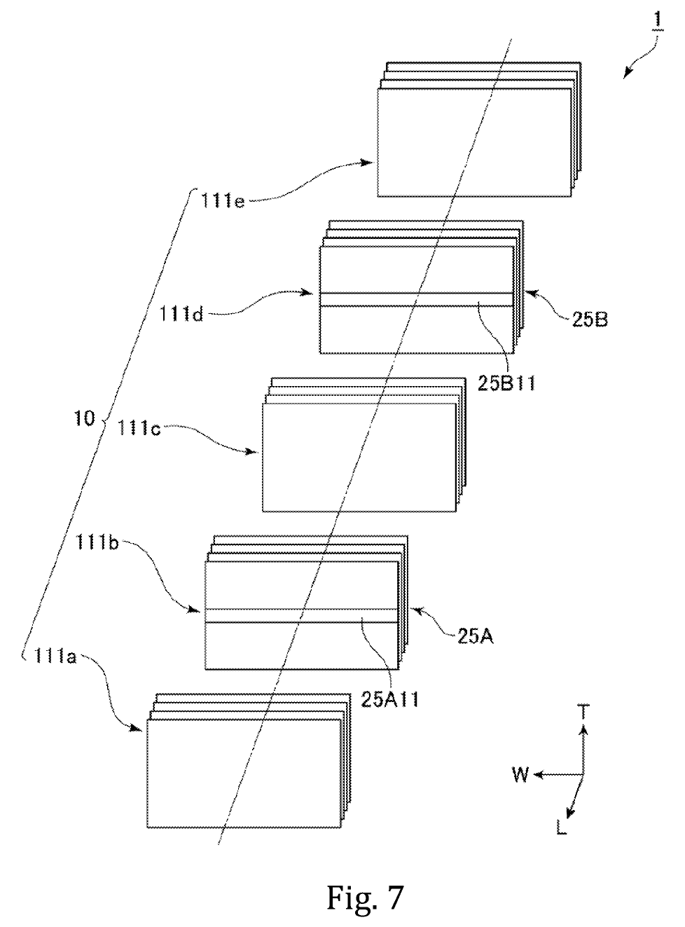

An inductor array according to another embodiment to which the invention is applicable will be now described with reference to FIGS. 7 to 13.

FIG. 7 illustrates a modification example of the inductor array 1. FIG. 7 is an exploded view of the inductor array 1 formed by stacking the magnetic layers in the L-axis direction. In the embodiment shown in FIG. 7, the base body 10 includes magnetic layers 111a to 111e. Each of the magnetic layers 111a to 111h is made of a magnetic material. The base body 10 includes the magnetic layer 111a, the magnetic layer 111b, the magnetic layer 111c, the magnetic layer 111d, and the magnetic layer 111e, which are stacked together in the stated order from the negative side to the positive side in the L-axis direction. The magnetic layer 111a and the magnetic layer 111e are disposed so as to cover the internal conductors 25A and 25B on both sides in the T-axis direction, and thus these magnetic layers may be referred to as the cover layers. In the illustrated embodiment, each of the magnetic layers 111a to 111e includes a plurality of magnetic films.

In the illustrated embodiment, a conductor pattern 25A11 forming the internal conductor 25A is provided on one surface of each of the plurality of magnetic films that form the magnetic layer 111b, and a conductor pattern 25B11 is provided on one surface of each of the plurality of magnetic films that form the magnetic layer 111d. The conductor patterns 25A11 and 25B11 are formed by, for example, printing a conductive paste made of a highly conductive metal or alloy on each magnetic sheet by screen printing. A conductive material contained in the conductive paste may be Ag, Pd, Cu, Al, or alloys thereof. The conductor patterns 25A11 and 25B11 may be formed using other methods and materials. For example, the conductor patterns 25A11 and 25B11 may be formed by sputtering, ink-jetting, or other known methods. The plurality of conductor patterns 25A11 may have the same or similar shapes to each other. Adjacent conductor patterns 25A11 among the plurality of conductor patterns 25A11 may be connected to each other in the base body 10, for example, by vias. The plurality of conductor patterns 25B11 may have the same or similar shapes to each other. Adjacent conductor patterns 25B11 among the plurality of conductor patterns 25B11 may be connected to each other in the base body 10, for example, by vias.

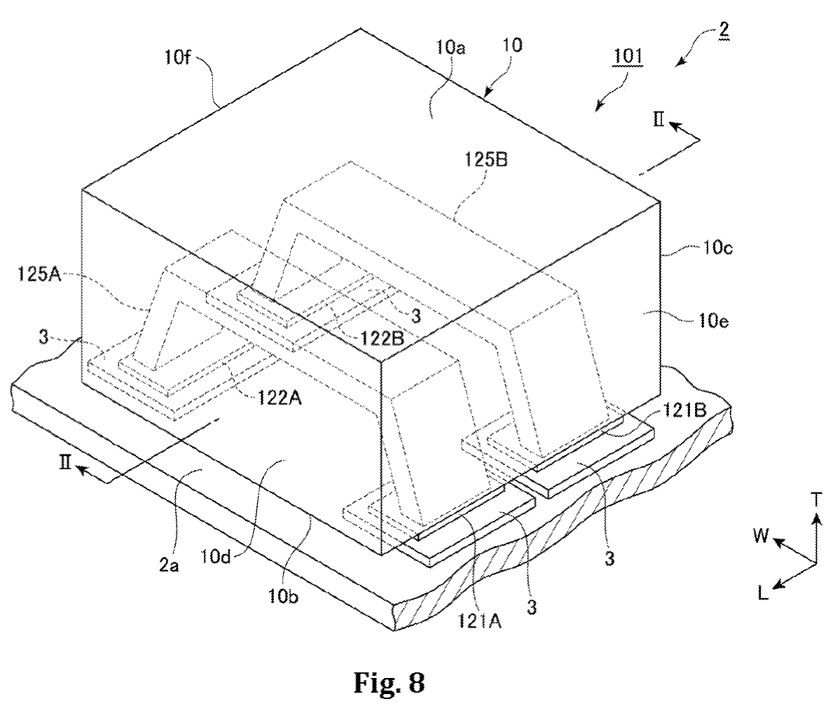

An inductor array 101 according to one or more embodiments of the invention will now be described with reference to FIGS. 8 to 11. The inductor array 101 shown in FIGS. 8 to 11 differs from the inductor array 1 in that it has internal conductors 125A and 125B instead of the internal conductors 25A and 25B, respectively, and external electrodes 121A, 122A, 121B, and 122B instead of the external electrodes 21A, 22A, 21B, and 22B, respectively. Description of the same elements or components of the inductor array 101 as the inductor array 1 will be hereunder omitted.

In the illustrated embodiment, the external electrodes 121A, 122A, 121B, 122B are all provided on the second principal surface 10b of the base body 10. The shapes of the external electrodes 121A, 122A, 121B, 122B are not limited to those shown. For example, the external electrodes 121A and 121B may be provided the base body 10 such that they are in contact with the second principal surface 10b and the first side surface 10e. The external electrodes 122A and 122B may be provided on the base body 10 such that they are in contact with the second principal surface 10b and the second side surface 10f.

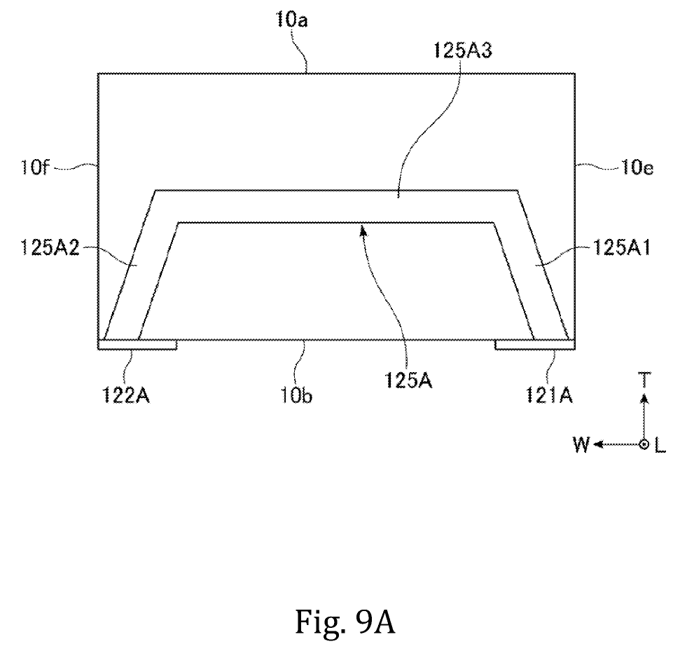

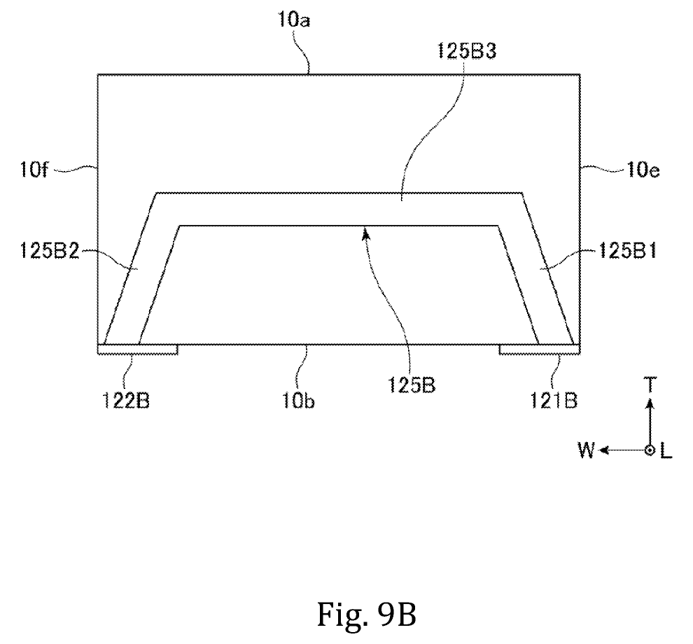

As shown in FIG. 9A, the internal conductor 125A is provided in the base body 10 so as to electrically connect between the external electrode 121A and the external electrode 122A. The internal conductor 125A includes a first portion 125A1, a second portion 125A2, and a third portion 125A3. The first portion 121A1 is connected to the external electrode 121A at one end and extends in an angled direction with respect to the T axis, and the second portion 125A2 is connected to the external electrode 122A at one end and extends in an angled direction with respect to the T axis. The third portion 125A3 extends in the W-axis direction and connects the other end of the first portion 121A1 with the other end of the second portion 121A2.

As shown in FIG. 9B, the internal conductor 125B is provided in the base body 10 so as to electrically connect between the external electrode 121B and the external electrode 122B, and has the same shape as the internal conductor 125A. The internal conductor 125B includes a first portion 125B1, a second portion 125B2, and a third portion 125B3. The first portion 121B1 is connected to the external electrode 121B at one end and extends in an angled direction with respect to the T axis, and the second portion 125B2 is connected to the external electrode 122B at one end and extends in an angled direction with respect to the T axis. The third portion 125B3 extends in the W-axis direction and connects the other end of the first portion 121B1 with the other end of the second portion 121B2.

The base body 10 of the inductor array 101 may include the magnetic layers 111a to 111e, similar to the embodiment of FIG. 7. In the illustrated embodiment, a conductor pattern forming the internal conductor 125A is provided on one surface of each of the plurality of magnetic films that form the magnetic layer 111b, and a conductor pattern forming the internal conductor 125B is provided on one surface of each of the plurality of magnetic films that form the magnetic layer 111d. Each of the plurality of conductor patterns forming the internal conductor 125A may have the shapes shown in FIG. 9A. Each of the plurality of conductor patterns forming the internal conductor 125B may have the shapes shown in FIG. 9B. The description of the conductor patterns 25A11 and 25B11 also applies to the conductor patterns that form the internal conductors 125A and 125B.

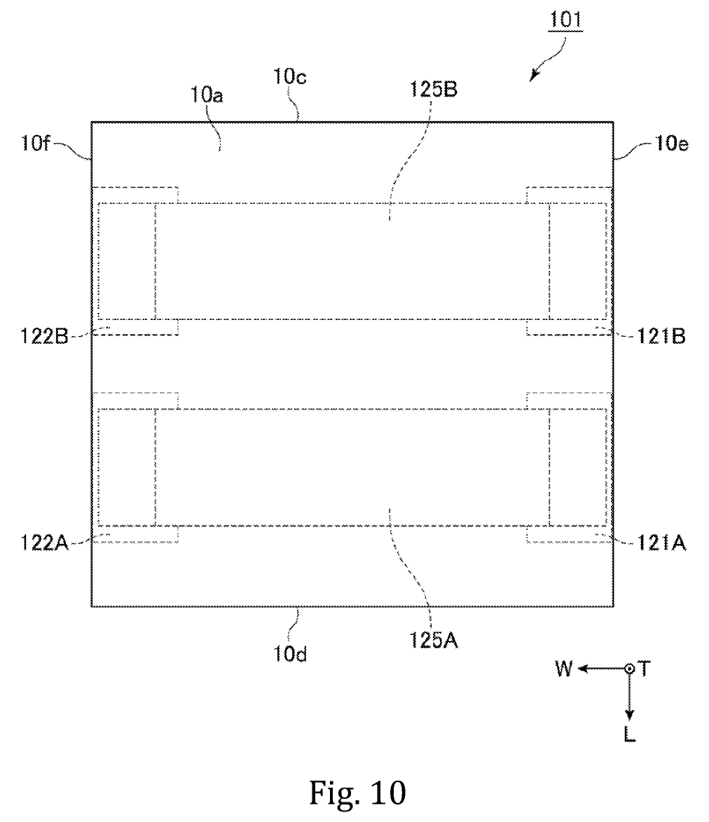

As shown in FIG. 10, the internal conductor 125A extends linearly from the external electrode 121A to the second external electrode 122A in plan view (as viewed from the T axis). For example, the internal conductor 125B may extend linearly from the external electrode 121B to the second external electrode 122B in plan view (as viewed from the T axis). In this way, the internal conductors 125A and 125B have no parts facing each other in the base body 10 in plan view. Since the internal conductors 125A and 125B have no parts facing each other in the base body 10 in plan view, the insulation reliability (withstand voltage) can be increased without changing the volume resistivity of the base body 10 compared with conventional inductors that have internal conductors with parts facing each other in plan view.

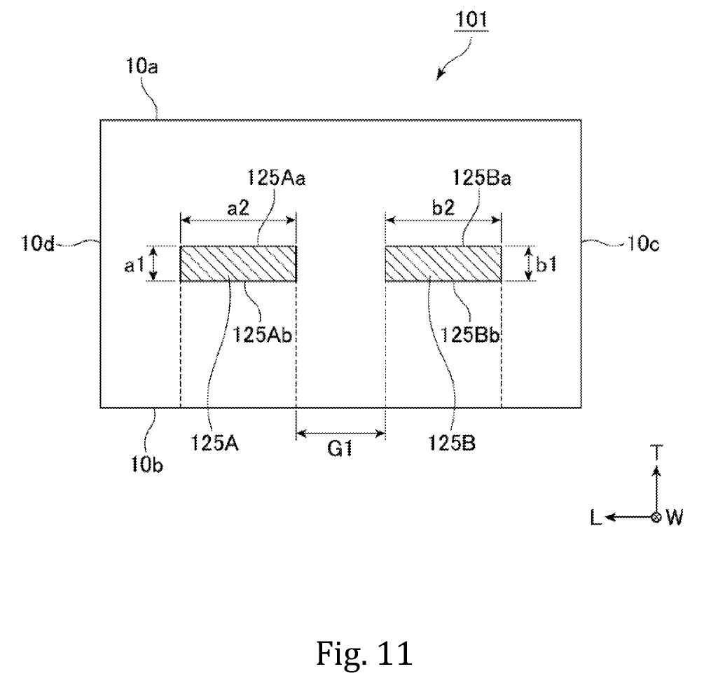

FIG. 11 is a schematic sectional view of the inductor array 101 along the line II-II. FIG. 11 shows sections of the internal conductors 125A and 125B cut along a plane that is parallel to the LT plane and passes the center of the base body 10. In the third portion 125A3 of the internal conductor 125A and the third portion 125B3 of the internal conductor 125B, the current flows in the W-axis direction. Thus, FIG. 11 shows an example of sections of the internal conductors 125A and 125B cut along the plane perpendicular to the direction of current flowing through the internal conductors 125A and 125B. The first aspect ratio of the internal conductor 125A is defined in the same way as the first aspect ratio of the internal conductor 25A, and the second aspect ratio of the internal conductor 125B is defined in the same way as the second aspect ratio of the internal conductor 25B. Specifically, the section of the internal conductor 125A cut along the plane perpendicular to the direction of the current flowing through the internal conductor 125A has a dimension a2 in the L-axis direction, and has a dimension a1 in a direction perpendicular to the L-axis direction. Here, the ratio of a1 to a2 (a1/a2) is defined as the first aspect ratio. Similarly, the section of the internal conductor 125B cut along the plane perpendicular to the direction of the current flowing through the internal conductor 125B has a dimension b2 in the L-axis direction, and has a dimension b1 in a direction perpendicular to the L-axis direction. Here, the ratio of b1 to b2 (b1/b2) is defined as the second aspect ratio. In one or more embodiments of the invention, the first aspect ratio of the internal conductor 125A is less than one (1). In one or more embodiments of the invention, the second aspect ratio of the internal conductor 125B is less than one (1).

The cutting plane for defining the first aspect ratio of the internal conductor 125A is not limited to the plane parallel to the LT plane shown in FIG. 11. The current flowing through the internal conductor 125A runs through the first portion 121A1 and the second portion 121A2 in the TW plane in the diagonal directions to the T-axis and W-axis, respectively. Thus when determining the first aspect ratio for the section of the first portion 121A1 or second portion 121A2, used are dimensions of sections of the internal conductor 125A cut in a plane parallel to the L-axis direction and diagonal to the W-axis direction and T-axis direction, respectively. The cutting plane for defining the second aspect ratio of the internal conductor 125B is not limited to the plane parallel to the LT plane shown in FIG. 11. The current flowing through the internal conductor 125A runs through the first portion 121B1 and the second portion 121B2 in the TW plane in the diagonal directions to the T-axis and W-axis, respectively. Thus when determining the second aspect ratio for the section of the first portion 121B1 or second portion 121B2, used are dimensions of sections of the internal conductor 125B cut in a plane parallel to the L-axis direction and diagonal to the W-axis direction and T-axis direction, respectively. In one or more embodiments of the invention, the first aspect ratio is less than one in any section of the internal conductor 125A orthogonal to the direction of the current flowing through the internal conductor 125A. In one or more embodiments of the invention, the second aspect ratio is less than one in any section of the internal conductor 125B orthogonal to the direction of the current flowing through the internal conductor 125B. In one or more embodiments of the invention, for the entire length of the internal conductors 25A and 25B along the direction of the current flowing through the internal conductors 125A and 125B, the first and second aspect ratios are less than one.

In one or more embodiments of the invention, the internal conductor 125B is disposed such that it overlaps the internal conductor 125A as viewed from the L-axis direction. As shown in FIG. 11, the position of an upper surface 125Aa of the internal conductor 125A in the T-axis direction may coincide with the position of an upper surface 125Ba of the internal conductor 125B in the T-axis direction. The position of a lower surface 125Ab of the internal conductor 125A in the T-axis direction may coincide with the position of the lower surface 125Bb of the internal conductor 125B in the T-axis direction. When these internal conductors are arranged in this way, it is possible to further improve the coupling coefficient between the internal conductor 125A and the internal conductor 125B, and also reduce the thickness of the inductor array 101.

In one or more embodiments of the invention, the internal conductor 125B may have the same shape as the internal conductor 125A. For example, the shape of the internal conductor 125B viewed from the L-axis direction may be the same as a shape of the internal conductor 125A viewed from the L-axis direction. By making the shape of the internal conductor 125A identical to the shape of the internal conductor 125B, it becomes easy to uniform the electrical characteristics of each line of inductor included in the inductor array 101.

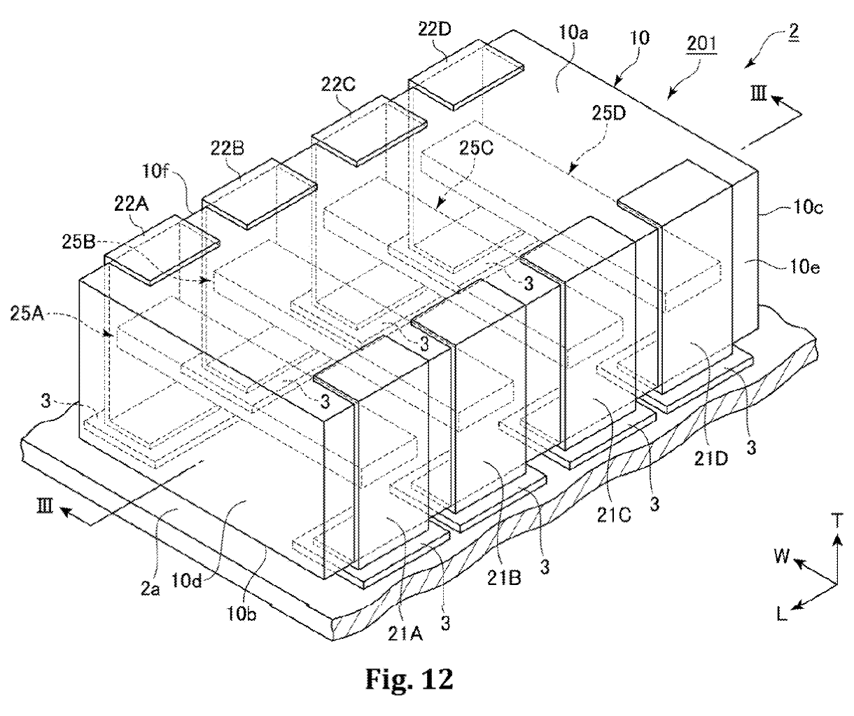

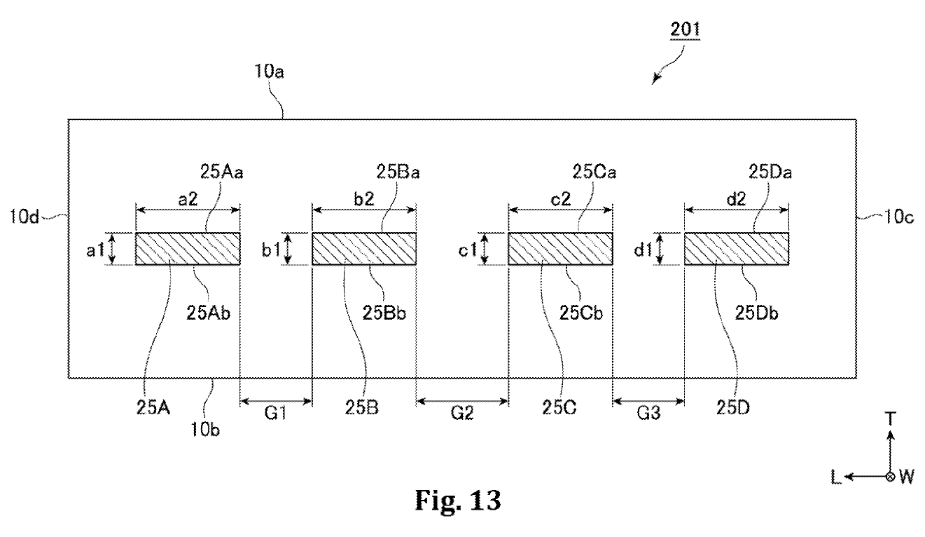

An inductor array 201 according to one or more embodiments of the invention will now be described with reference to FIGS. 12 and 13. The inductor array 201 has four internal conductors and four sets of the external electrodes whereas the inductor array 1 has the two internal conductors and the two sets of the external electrodes. Description of the same elements or components of the inductor array 201 as the inductor array 1 will be hereunder omitted.

The inductor array 201 includes internal conductors 25A, 25B, 25C, and 25D provided in the base body 10 and external electrodes 21A, 21B, 21C, 21D, 22A, 22B, 22C, and 22D provided on a surface of the base body 10. The internal conductors 25A and 25B are configured and disposed in the same manner as the internal conductors 25A and 25B in the inductor array 1. The internal conductor 25C is coupled to the external electrode 21C at one end and to the external electrode 22C at the other end. The internal conductor 25D is coupled to the external electrode 21D at one end and to the external electrode 22D at the other end. Thus, the inductor array 201 includes a first inductor including the internal conductor 25A and the external electrodes 21A and 22A, a second inductor including the internal conductor 25B and the external electrodes 21B and 22B, a third inductor including the internal conductor 25C and the external electrodes 21C and 22C, and a third inductor including the internal conductor 25D and the external electrodes 21D and 22D. The eight external electrodes 21A to 21D, and 22A to 22D of the inductor array 201 are arranged to face the corresponding lands 3 respectively when the inductor array 201 is mounted on the mounting substrate 2a.

In the illustrated embodiment, the internal conductor 25C is disposed on the opposite side to the internal conductor 25A with respect to the internal conductor 25B in the L-axis direction. The internal conductor 25D is disposed on the opposite side to the internal conductor 25B with respect to the internal conductor 25C in the L-axis direction. The internal conductors 25A, 25B, 25C, and 25D are arranged in this order from the positive side to the negative side in the L-axis direction. The internal conductor 25A faces the second end surface 10d of the base body 10 on one side of the direction along a first coil axis Ax1 (positive side of the L-axis direction). In other words, there are no internal conductors between the internal conductor 25A and the second end surface 10d. The internal conductor 25D faces the first end surface 10c of the base body 10 on one side of the direction along a fourth coil axis Ax4 (negative side of the L-axis direction). In other words, there are no internal conductors between the internal conductor 25D and the first end surface 10c. The second and third internal conductors 25B and 25C are disposed between the first and second internal conductors 25A and 25C.

As described above, the internal conductor 25B is disposed at the distance G1 from the internal conductor 25A in the L-axis direction. The internal conductor 25G is disposed at a distance G2 from the internal conductor 25B in the L-axis direction. The internal conductor 25D is disposed at a distance G3 from the internal conductor 25C in the L-axis direction. In one or more embodiments of the invention, the distance G1 between the internal conductors 25A and the internal conductor 25B is smaller than the distance G2 between the internal conductor 25B and the internal conductor 25C. In one or more embodiments of the invention, the distance G3 between the internal conductors 25C and the internal conductor 25D is smaller than the distance G2 between the internal conductor 25B and the internal conductor 25C. The distance G1 may be equal to or different from the distance G3. The distance G2 between the internal conductor 25B and the internal conductor 25C may be 0.3 mm or less. The shapes of the internal conductors 25A, 25B, 25C, and 25D viewed from the L-axis direction may be the same as each other. By making the shapes of the internal conductors 25A, 25B, 25C, and 25D same to each other, it becomes easy to uniform the electrical characteristics of each line of inductor included in the inductor array 201.

In the illustrated embodiment, the internal conductor 25C has a rectangular parallelepiped shape. Thus, when a voltage is applied between the external electrode 21C and the external electrode 22C, the current flows through the internal conductor 25C along the W axis. In the illustrated embodiment, the internal conductor 25D has a rectangular parallelepiped shape. Thus, when a voltage is applied between the external electrode 21D and the external electrode 22D, the current flows through the internal conductor 25D along the W axis.

Referring to FIG. 13, the aspect ratios of the internal conductors 25C and 25D will be described. FIG. 13 is a sectional view of an inductor array 201 along the line III-III schematically showing sections of the internal conductors 25A, 25B, 25C, and 25D cut along a plane perpendicular to the W-axis direction. Since the current flows in the W-axis direction through each of the internal conductors 25A, 25B, 25C, and 25D as described above, FIG. 13 illustrates an example of cross sections of the internal conductors 25A, 25B, 25C, and 25D cut along the plane orthogonal to the direction of current flowing through the internal conductors 25A, 25B, 25C, and 25D.

As shown in FIG. 13, the section of the internal conductor 25A cut along the plane perpendicular to the direction of the current flowing through the internal conductor 25A has a dimension c2 in a reference direction and a dimension c1 in a direction perpendicular to the reference direction. In the illustrated embodiment, the reference direction coincides with the L-axis direction, and the direction perpendicular to the reference direction of the section of the internal conductor 25C cut along the plane perpendicular to the current flowing direction coincides with the T-axis direction. The ratio of c1 to c2 (c1/c2) is defined as a third aspect ratio. In one or more embodiments of the invention, the third aspect ratio is less than one (1). Similarly, the section of the internal conductor 25D cut along a plane perpendicular to the direction of the current flowing through the internal conductor 25D has a dimension d2 in a reference direction and a dimension d1 in a direction perpendicular to the reference direction. In the illustrated embodiment, the reference direction coincides with the L-axis direction, and the direction perpendicular to the reference direction of the section of the internal conductor 25D cut along the plane perpendicular to the current flowing direction coincides with the T-axis direction. The ratio of d1 to d2 (d1/d2) is defined as a fourth aspect ratio. In one or more embodiments of the invention, the fourth aspect ratio of the internal conductor 25D is less than one (1).

In one or more embodiments of the invention, not only for the sections of the internal conductors 25C and 25D cut along the plane that is parallel to the LT plane and passes the center of the base body 10 as illustrated in FIG. 13, but also for any section of the internal conductor 25C orthogonal to the direction of the current flowing through the internal conductor 25C, the third aspect ratio is less than one, and for any section of the internal conductor 25D orthogonal to the direction of the current flowing through the internal conductor 25D, the fourth aspect ratio is less than one. In one or more embodiments of the invention, for the entire length of the internal conductors 25C and 25D along the direction of the current flowing through the internal conductors 25C and 25D, the third and fourth aspect ratios are less than one.

The inductor array 201 may include three inductors or five or more inductors. The aspect ratio of each internal conductor provided in the inductor array 201 is defined in the same way as the first aspect ratio of the internal conductor 25A. The aspect ratio of each internal conductor provided in the inductor array 201 is less than one.

In one or more embodiments of the invention, the internal conductors 25A, 25B, 25C, and 25D are disposed such that they overlap with each other as viewed from the L-axis direction. As shown in FIG. 13, the position of an upper surface 25Aa of the internal conductor 25A in the T-axis direction, the position of an upper surface 25Ba of the internal conductor 25B in the T-axis direction, the position of an upper surface 25Ca of the internal conductor 25C in the T-axis direction, and the position of an upper surface 25Da of the internal conductor 25D in the T-axis direction may all coincide. The position of a lower surface 25Ab of the internal conductor 25A in the T-axis direction, the position of a lower surface 25Bb of the internal conductor 25B in the T-axis direction, the position of a lower surface 25Cb of the internal conductor 25C in the T-axis direction, and the position of a lower surface 25Db of the internal conductor 25D in the T-axis direction may all be coincident. When these internal conductors are arranged in this way, it is possible to further improve the coupling coefficient between the internal conductor 125A and the internal conductor 125B, and also reduce the thickness of the inductor array 201.

In one or more embodiments of the invention, the internal conductors 25A, 25B, 25C, and 25D may all have the same. In this way, it is possible to easily uniform the electrical characteristics of the lines of inductors included in the inductor arrays 201.

Next, a description is given of an example of a method of manufacturing the inductor array 1 according to one embodiment of the present invention. FIG. 2 will be referred to as necessary to describe the method. In one or more embodiments of the invention, the inductor array 1 is produced by a sheet lamination method in which magnetic sheets are stacked together. The first step of the sheet lamination method for producing the inductor array 1 is to prepare the magnetic sheets. The magnetic sheets are formed from a slurry obtained by kneading metal magnetic particles made of a soft magnetic material with a resin. The slurry is molded into the insulating sheets using a sheet molding machine such as a doctor blade sheet molding machine. The resin material kneaded together with the metal magnetic particles may be, for example, a polyvinyl butyral (PVB) resin, an epoxy resin, or any other resin materials having an excellent insulation property.

The magnetic sheets are cut in a predetermined shape(s). Next, a conductive paste is applied to the magnetic sheets cut into the predetermined shape(s) by a known method such as screen printing, thereby forming a plurality of unfired conductor patterns that will later form the conductor patterns 25A1 to 25A3 and the conductor patterns B1 to B3 after firing. Specifically, unfired conductor patterns that will later be the conductor patterns 25A1 and 25B1 are formed on the magnetic sheet that will later be the magnetic layer 11b, unfired conductor patterns that will later be the conductor patterns 25A2 and 25B2 are formed on the magnetic sheet that will later be the magnetic layer 11c, and unfired conductor patterns that will later be the conductor patterns 25A3 and 25B3 are formed on the magnetic sheet that will later be the magnetic layer 11d. The conductive paste is obtained by, for example, kneading Ag, Cu or an alloy of these metals with a resin. A through-hole(s) may be formed in a predetermined position of the cut magnetic body sheet in the thickness direction. When a through hole is formed in the magnetic sheet, the through hole in the magnetic sheet is filled with a conductor paste during the formation of the unfired conductor patterns, and the adjacent conductor patterns are connected to each other by unfired vias embedded in the through holes.

When manufacturing the inductor array 1 that has the stacked structure shown in FIG. 7, unfired conductor patterns that later become the conductor patterns 25A1, 25A2, 25A3, 25B1, 25B2, and 25B3 respectively may be formed on different magnetic sheets.

As described above, the magnetic sheets on or in which the unfired conductor patterns and the unfired vias formed and the magnetic sheets on which no conductor is formed are obtained, and these sheets are stacked to obtain a mother laminate. The dimensions of the internal conductor 25A and the internal conductor 25B in the T-axis direction (a1 and b1 in the illustrated embodiment) can be adjusted by the number of magnetic sheets on which the conductor patterns (e.g., conductor patterns 25A1 to 25A3 and 25B1 to 25B3) are formed.

Next, the mother laminate is diced using a cutter such as a dicing machine or a laser processing machine to obtain a chip laminate.

Subsequently, the chip laminate is subjected to heat treatment at 600°C to 850°C for 20 minutes to 120 minutes. This heat treatment degreases the chip laminate, and the magnetic sheets and the conductor paste are fired to obtain the base body 10 that includes the internal conductors 25A and 25B thereinside. If the magnetic sheet contains a thermosetting resin, the thermosetting resin may be cured by performing a heat treatment at a lower temperature onto the chip laminate. This cured resin serves as the binder that binds the metal magnetic particles contained in the magnetic sheet together. The heat treatment is performed onto the chip laminate at a temperature of 100℃ to 200℃ for a duration of 20 to 120 minutes, for example.

Following the heat treatment, a conductive paste is applied to the surface of the chip laminate (that is, the base body 10) to form the external electrodes 21A, 22A, 21B and 22B. Through the above described process, the inductor array 1 is obtained. The inductor arrays 101 and 201 can also be manufactured by the same method as the inductor array 1.

The above-described manufacturing method can be modified by omitting some of the steps, adding steps not explicitly described, and/or reordering the steps. Such omission, addition, or reordering is also included in the scope of the present invention unless diverged from the purport of the present invention.

The inductor array 1 can be made in different manners than the method described above. The inductor array 1 can be fabricated by various known methods. The inductor array 1 may be fabricated by a sheet lamination method, a printing lamination method, a thin film process, a compression molding process, or any other known methods.

Advantageous effects of the above embodiments will be now described. According to one or more embodiments of the invention, the internal conductor 25A is configured in the base body 10 such that it is connected at one end thereof to the external electrode 21A and connected at the other end thereof to the external electrode 22A. When the inductor array 1 is in use, an electric current flows through the internal conductor 25A. When the section of the internal conductor 25A cut along the plane perpendicular to the direction of the current flowing therein has the dimension a2 in the L-axis direction and dimension a1 in the direction perpendicular to the L-axis direction, the first aspect ratio, which is the ratio of the dimension a1 to the dimension a2 (a1/a2), is smaller than one. Thus the magnetic flux generated when the current flows through the internal conductor 25A is more likely to be oriented in the L-axis direction since the first aspect ratio is less than one. This makes it easier for the magnetic flux generated around the internal conductor 25A to reach the internal conductor 25B, which is disposed spaced away from the internal conductor 25A in the L-axis direction. When the section of the internal conductor 25B cut along the plane perpendicular to the direction of the current flowing therein has the dimension b2 in the L-axis direction and dimension b1 in the direction perpendicular to the L-axis direction, the second aspect ratio, which is the ratio of the dimension b1 to the dimension b2 (b1/b2), is smaller than one. Thus the magnetic flux generated when the current flows through the internal conductor 25B is more likely to be oriented in the L-axis direction since the second aspect ratio is less than one. This makes it easier for the magnetic flux generated around the internal conductor 25B to reach the internal conductor 25A, which is disposed spaced away from the internal conductor 25B in the L-axis direction. As a result of the above, the magnetic coupling between the internal conductor 25A and the internal conductor 25B can be improved in the inductor array 1. The inductor arrays 101 and 201 have the same advantageous effect.

In the inductor arrays with the base body including metal magnetic particles, short circuit may occur between the internal conductors. To avoid short circuit between the internal conductors, it is desirable to increase the distance between the internal conductors. According to one or more embodiment of the invention, even when the distance between the internal conductor 25A and the internal conductor 25B is increased, it is possible to improve the magnetic coupling between these internal conductors by making the first aspect ratio of the internal conductor 25A and the second aspect ratio of the internal conductor 25B less than one.

The inductor arrays with the base body including the metal magnetic particles tend to have a lower specific magnetic permeability than array type inductors with the base body formed of a ferrite material. Therefore, if the magnetic coupling between the internal conductors is improved by the air gap provided between the internal conductors, the specific magnetic permeability will be further decreased. Therefore, in the inductor arrays with the base body including the metal magnetic particles, it is desirable not to provide the air gap in the base body. In the inductor arrays 1, 101, 201 according to one or more embodiment of the invention, by making the first aspect ratio of the internal conductor 25A and the second aspect ratio of the internal conductor 25B less than one, it is possible to improve the magnetic coupling between these internal conductors without the air gap in the base body 10.

According to one or more embodiments of the invention, by making the first aspect ratio of the internal conductor 25A and the second aspect ratio of the internal conductor 25B less than one, the dimension in the T-axis direction (thickness direction) of the base body 10 can be reduced. Thus, according to one or more embodiments of the invention, it is possible to provide the inductor arrays 1, 101, 201 in which the magnetic coupling between the internal conductors is improved and the dimension in the thickness direction is reduced.

In one or more embodiments of the invention, the third aspect ratio of the internal conductor 25C may be less than one (1). In this case, the magnetic coupling between the internal conductor 25C and other adjacent internal conductors in the L-axis direction (e.g., the internal conductors 25B and 25D) can be improved. In one or more embodiments of the invention, the fourth aspect ratio of the internal conductor 25D may be less than one (1). In this case, the magnetic coupling between the internal conductor 25D and other adjacent internal conductors in the L-axis direction (e.g., the internal conductor 25C) can be improved.

In the inductor array 201 according to one or more embodiments of the present invention, the internal conductor 25B and the internal conductor 25C are disposed between the internal conductor 25A and the internal conductor 25D in the L-axis direction. Therefore, the magnetic flux generated from the internal conductor 25B and the magnetic flux generated from the internal conductor 25C are less likely to leak outside the base body 10 compared to the magnetic flux generated from the internal conductors 25A and 25D. Whereas the magnetic flux generated from the internal conductor 25A is more likely to leak outside the base body 10 since the internal conductor 25A faces the second end surface 10d of the base body 10 in the L-axis direction. Similarly the magnetic flux generated from the internal conductor 25D is more likely to leak outside the base body 10 since the internal conductor 25D faces the first end surface 10c of the base body 10 in the L-axis direction. Therefore, the magnetic coupling between the internal conductor 25A and the internal conductor 25B and between the internal conductor 25C and the internal conductor 25D is likely to be weaker than the magnetic coupling between the internal conductor 25B and the internal conductor 25C. According to one or more embodiments of the invention, the spacing G1 between the internal conductor 25A and the internal conductor 25B is smaller than the spacing G2 between the internal conductor 25B and the internal conductor 25C, thereby strengthening the magnetic coupling between the internal conductor 25A and the internal conductor 25B, and consequently it is possible to make the magnetic coupling between the internal conductor 25A and the internal conductor 25B as strong as the magnetic coupling between the internal conductor 25B and the internal conductor 25C. According to one or more embodiments of the invention, the spacing G3 between the internal conductor 25C and the internal conductor 25D is smaller than the spacing G2 between the internal conductor 25B and the internal conductor 25C, thereby strengthening the magnetic coupling between the internal conductor 25C and the internal conductor 25D, and consequently it is possible to make the magnetic coupling between the internal conductor 25C and the internal conductor 25D as strong as the magnetic coupling between the internal conductor 25B and the internal conductor 25C.

According to one or more embodiments of the invention, since the internal conductor 25A and the internal conductor 25B are arranged in the positions where they overlap each other as viewed from the L-axis direction, the magnetic coupling between the internal conductor 25A and the internal conductor 25B can be enhanced without increasing the dimension of the base body in the direction perpendicular to the L-axis direction (T-axis direction).

In one or more embodiments of the invention, when the internal conductor 25A and the internal conductor 25B are spaced apart in the L-axis direction, the shape of the internal conductor 25A viewed from the L-axis direction is identical to the shape of the internal conductor 25B, so that the inductor including the internal conductor 25A and the inductor including the internal conductor 25B will behave similarly to external factors (e.g., electromagnetic influence from external elements). The same effect is achieved when the shape of the internal conductor 125A viewed from the L-axis direction is the same as the shape of the internal conductor 125B, and when the shape of the internal conductor 225A (e.g., a shape of a winding portion 226A) viewed from the L-axis direction is the same as the shape of the internal conductor 225B (e.g., a shape of the winding portion 226B). When the shapes of the internal conductors 25A, 25B, 25C, and 25D viewed from the L-axis direction are identical to each other, the four inductors that include these internal conductors can be configured to exhibit similar behavior to external factors.

The dimensions, materials, and arrangements of the constituent elements described herein are not limited to those explicitly described for the embodiments, and these constituent elements can be modified to have any dimensions, materials, and arrangements within the scope of the present invention. Furthermore, constituent elements not explicitly described herein can also be added to the described embodiments, and it is also possible to omit some of the constituent elements described for the embodiments.

What is claimed is:

1. An inductor array, comprising:
a base body containing a plurality of metal magnetic particles and having a first surface, the base body including a plurality of magnetic layers laminated in a lamination direction;
a first external electrode provided on the base body in contact with at least the first surface;
a second external electrode provided on the base body in contact with at least the first surface;
a third external electrode provided on the base body in contact with at least the first surface;
a fourth external electrode provided on the base body in contact with at least the first surface;
a fifth external electrode provided on the base body in contact with at least the first surface;
a sixth external electrode provided on the base body in contact with at least the first surface;
a first internal conductor provided in the base body and connected to the first external electrode at one end and to the second external electrode at the other end, the first internal conductor including a plurality of first conductor patterns, each provided on a corresponding one of the plurality of magnetic layers and connected to the first external electrode and the second external electrode, a section of the first internal conductor orthogonal to a direction of electric current flowing therethrough having a dimension in a reference direction and a dimension in a direction perpendicular to the reference direction, and a first aspect ratio, which is a ratio of the dimension in the reference direction to the dimension in the direction perpendicular to the reference direction, being less than 0.5;
a second internal conductor provided in the base body such that the second internal conductor is spaced away from the first internal conductor in the reference direction, the second internal conductor being connected to the third external electrode at one end and to the fourth external electrode at the other end, the second internal conductor including a plurality of second conductor patterns, each provided on a corresponding one of the plurality of magnetic layers and connected to the third external electrode and the fourth external electrode, a section of the second internal conductor orthogonal to a direction of electric current flowing therethrough having a dimension in the reference direction and a dimension in a direction perpendicular to the reference direction, and a second aspect ratio, which is a ratio of the dimension in the reference direction to the dimension in the direction perpendicular to the reference direction, being less than 0.5; and
a third internal conductor provided in the base body such that the third internal conductor is spaced away from the second internal conductor in the reference direction and disposed on a side opposite to the first internal conductor with respect to the second internal conductor, the third internal conductor being connected to the fifth external electrode at one end and to the sixth external electrode at the other end, the third internal conductor including a plurality of third conductor patterns, each provided on a corresponding one of the plurality of magnetic layers and connected to the fifth external electrode and the sixth external electrode, a section of the third internal conductor orthogonal to a direction of electric current flowing therethrough having a dimension in the reference direction and a dimension in a direction perpendicular to the reference direction, and a third aspect ratio, which is a ratio of the dimension in the reference direction to the dimension in the direction perpendicular to the reference direction, being less than 0.5,
wherein the first internal conductor extends linearly from the first external electrode to the second external electrode as viewed from a direction perpendicular to the first surface,
wherein the second internal conductor extends linearly from the third external electrode to the fourth external electrode as viewed from the direction perpendicular to the first surface, and
wherein the third internal conductor extends linearly from the fifth external electrode to the sixth external electrode as viewed from the direction perpendicular to the first surface.

2. The inductor array of claim 1, wherein a shape of the first internal conductor is identical to a shape of the second internal conductor as viewed from the reference direction.

3. The inductor array of claim 2, wherein a shape of the third internal conductor is identical to a shape of the first or second internal conductor or both as viewed from the reference direction.

4. The inductor array of claim 1, wherein the second internal conductor is disposed at a position where the second internal conductor overlaps the first internal conductor as viewed from the reference direction.

5. The inductor array of claim 4, wherein the third internal conductor is disposed at a position where the third internal conductor overlaps the first internal conductor and the second internal conductor as viewed from the reference direction.

6. The inductor array of claim 1, wherein the base body has a first end surface connected to the first surface,
wherein the first internal conductor is arranged such that the first internal conductor faces the first end surface of the base body in the reference direction, and
wherein a distance between the first internal conductor and the second internal conductor in the reference direction is smaller than a distance between the second internal conductor and the third internal conductor in the reference direction.

7. The inductor array of claim 1, further comprising:
a seventh external electrode provided on the base body in contact with at least the first surface;
an eighth external electrode provided on the base body in contact with at least the first surface; and
a fourth internal conductor provided in the base body such that the fourth internal conductor is spaced away from the third internal conductor in the reference direction and disposed on a side opposite to the second internal conductor with respect to the third internal conductor, the fourth internal conductor being connected to the seventh external electrode at one end and to the eighth external electrode at the other end, the fourth internal conductor including a plurality of fourth conductor patterns, each provided on a corresponding one of the plurality of magnetic layers and connected to the seventh external electrode and the eighth external electrode, a section of the fourth internal conductor orthogonal to a direction of electric current flowing therethrough having a dimension in the reference direction and a dimension in a direction perpendicular to the reference direction, and a fourth aspect ratio, which is a ratio of the dimension in the reference direction to the dimension in the direction perpendicular to the reference direction, being less than 0.5,
wherein the fourth internal conductor extends linearly from the seventh external electrode to the eighth external electrode as viewed from the direction perpendicular to the first surface.

8. The inductor array of claim 7, wherein a shape of the fourth internal conductor is identical to a shape of at least one of the first, second, or third internal conductor as viewed from the reference direction.

9. The inductor array of claim 7, wherein the third internal conductor is disposed at a position where the fourth internal conductor overlaps the first internal conductor, the second internal conductor and the third internal conductor as viewed from the reference direction.

10. The inductor array of claim 7, wherein the base body has a second end surface that is connected to the first surface and opposes the first end surface,
wherein the fourth internal conductor is arranged such that the fourth internal conductor faces the second end surface of the base body in the reference direction, and
wherein a distance between the third internal conductor and the fourth internal conductor in the reference direction is smaller than a distance between the second internal conductor and the third internal conductor in the reference direction.

11. The inductor array of claim 1, wherein the base body has a first side surface and a second side surface opposing the first side surface,
wherein the first internal conductor is exposed at one end thereof to outside of the base body from the first side surface and is connected to the first external electrode at the one end, and the first internal conductor is also exposed at the other end thereof to outside of the base body from the second side surface and is connected to the second external electrode at the other end, and
wherein the second internal conductor is exposed at one end thereof to outside of the base body from the first side surface and is connected to the third external electrode at the one end, and the second internal conductor is also exposed at the other end thereof to outside of the base body from the second side surface and is connected to the fourth external electrode at the other end.

12. The inductor array of claim 7, wherein the first, second, third and fourth internal conductors are configured and arranged to remove common mode noise in a differential transmission circuit.

13. The inductor array of claim 1, wherein a relative magnetic permeability of the base body is in the range of 30 to 100.

14. The inductor array of claim 1, wherein each of the first, second, and third aspect ratios is less than 0.4.

15. The inductor array of claim 1, wherein each of the first, second, and third aspect ratios is less than 0.3.

16. The inductor array of claim 1, wherein each of the first, second, and third aspect ratios is less than 0.2.

17. The inductor array of claim 1, wherein each of the first, second, and third aspect ratios is less than 0.1.

18. The inductor array of claim 1, wherein each of the first, second, and third aspect ratios is less than 0.05.

19. A circuit board comprising the inductor array of claim 1.

20. An electronic device comprising the circuit board of claim 19.
